(19) United States
(12) Patent Application Publication
(10) Pub. No.: US 2005/0087878 A1
(43) Pub. Date: Apr. 28, 2005

(54) Semiconductor device

(75) Inventors: Katsuhiro Uesugi, Hyogo (JP); Kiyoshi Maeda, Hyogo (JP); Kenji Tabaru, Hyogo (JP)

Correspondence Address: McDermott, Will & Emery, 600 13th Street, N.W., Washington, DC, 20005-3096, US

(73) Assignee: RENESAS TECHNOLOGY CORP.

(21) Appl. No.: 10/821,872

(22) Filed: Apr. 12, 2004

(30) Foreign Application Priority Data
Oct. 23, 2003 (JP) 2003-363562(P)

(51) Int. Cl. H01L 21/4763

(52) U.S. Cl. 257/758

(57) ABSTRACT

A semiconductor device includes a silicon substrate having a main surface, a memory cell formed on the main surface, and an interlayer insulating film formed on the main surface to cover the memory cell. The interlayer insulating film has a top surface and a peripheral edge. In the interlayer insulating film, grooves are formed to be placed between the memory cell and the peripheral edge, to extend in parallel with the main surface and to extend in a predetermined direction at a spacing with each other, and a groove is formed to diverge from the grooves and to extend in a direction different from the extending direction of the grooves. The semiconductor device further includes metal film filling the grooves. Thus, crack propagation from the peripheral edge to the inside of the interlayer insulating film can surely be prevented to provide a semiconductor device with high reliability.

### BACKGROUND OF THE INVENTION

1. Field of the Invention

This invention generally relates to a semiconductor device, and more particularly, to a semiconductor device where a multi-layer interlayer insulating film is formed on a semiconductor substrate.

2. Description of the Background Art

Japanese Patent Laying-Open No. 8-172062 discloses a semiconductor wafer and its manufacturing method which aim at ensuring adhesion between a protection film and functional wiring. The semiconductor wafer disclosed therein has a peripheral edge pattern formed on the protection film along scribe lines along which the wafer is to be diced with a dicing saw, located between the scribe lines and the functional wiring formed in the substrate's region intended for a semiconductor device. The formation of such a peripheral edge pattern can prevent the force, which is applied to a peripheral edge of the protection film along the scribe lines when the wafer is diced with a dicing saw, from being conveyed to the area at the inner side of the peripheral edge pattern.

In addition, Japanese Patent Laying-Open No. 3-30357 discloses a semiconductor chip and its manufacturing method which prevent a crack, which is caused by dicing the wafer to obtain a semiconductor chip, from intruding into a region intended for an electronic element. In addition, Japanese Patent Laying-Open No. 11-340167 discloses a semiconductor device and its manufacturing method which prevent peeling of a sputter film, which is caused by poor coverage inside and in the periphery of the chip.

As such, the semiconductor wafer disclosed in Japanese Patent Laying-Open No. 8-172062 has a peripheral edge pattern formed on a protection film so as to reduce damage when the wafer is diced with a dicing saw. However, the protection film can be damaged in other occasions in addition to dicing with a dicing saw. For example, when a multi-layer interlayer insulating film is formed on a semiconductor substrate, a crack occurs inside the interlayer insulating film or at the border of the deposited interlayer insulating film because of difference in hygroscopicity, thermal expansion, and the like. When a semiconductor device is used under the circumstance of high temperature and high humidity, the interlayer insulating film absorbs moisture, which also causes a crack.

Such a crack initially occurs at the peripheral edge of the interlayer insulating film exposed to the atmosphere, and then propagates toward the inside of the interlayer insulating film. The peripheral edge pattern disclosed in Japanese Patent Laying-Open No. 8-172062, however, cannot surely inhibit the propagation of a crack. As a result, a crack reaches inside the semiconductor device, which adversely affects the reliability of the semiconductor device. Similarly, the semiconductor chip disclosed in Japanese Patent Laying-Open No. 3-30357 and the semiconductor device disclosed in Japanese Patent Laying-Open No. 11-340167 cannot solve such a problem.

### SUMMARY OF THE INVENTION

Therefore, an object of the present invention is to solve the problem described above, and more particularly, to surely inhibit crack propagation from the peripheral edge to the inside of an interlayer insulating film to provide a semiconductor device with high reliability.

A semiconductor device according to the present invention includes: a semiconductor substrate having a main surface; a semiconductor element formed on the main surface; and an interlayer insulating film formed on the main surface to cover the semiconductor element. The interlayer insulating film has a top surface and a peripheral edge extending from the top surface to the main surface. In the interlayer insulating film, strip-like first and second groove portions are formed to be placed between the semiconductor element and the peripheral edge, to extend in parallel with the main surface and to extend in a predetermined direction at a spacing with each other, and a plurality of third groove portions are formed to diverge from the first and second groove portions to extend in a direction different from the extending direction of the first and second groove portions. The semiconductor device further includes a metal to fill the first, second and third groove portions.

According to the present invention, crack propagation from the peripheral edge to the inside of an interlayer insulating film can surely be inhibited to provide a semiconductor device with high reliability.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a perspective view showing a semiconductor wafer from which a semiconductor device according to a first embodiment of the present invention is obtained.

FIG. 2 shows a cross section taken along an arrow II-II in FIG. 1.

FIG. 3 shows a cross section taken along an arrow III-III in FIG. 2.

FIG. 4 shows a cross section taken along an arrow IV-IV in FIG. 2.

FIGS. 5 to 8 show a cross section illustrating a step of a method of manufacturing a semiconductor device in FIG. 3.

FIG. 9 shows a cross section illustrating the condition of a crack occurring in the semiconductor device in FIG. 3.

FIG. 10 shows a cross section illustrating a semiconductor device according to a second embodiment of the present invention.

FIG. 11 shows a cross section illustrating a semiconductor device according to a third embodiment of the present invention.

FIG. 12 shows a cross section illustrating a semiconductor device according to a fourth embodiment of the present invention.

FIG. 13 shows a cross section illustrating a semiconductor device according to a fifth embodiment of the present invention.

FIG. 14 shows a cross section illustrating a semiconductor device according to a sixth embodiment of the present invention.

FIG. 15 shows a cross section illustrating a semiconductor device according to a seventh embodiment of the present invention.

### DESCRIPTION OF THE PREFERRED EMBODIMENTS

Embodiments of the present invention will now be described in connection with the drawings.

### First Embodiment

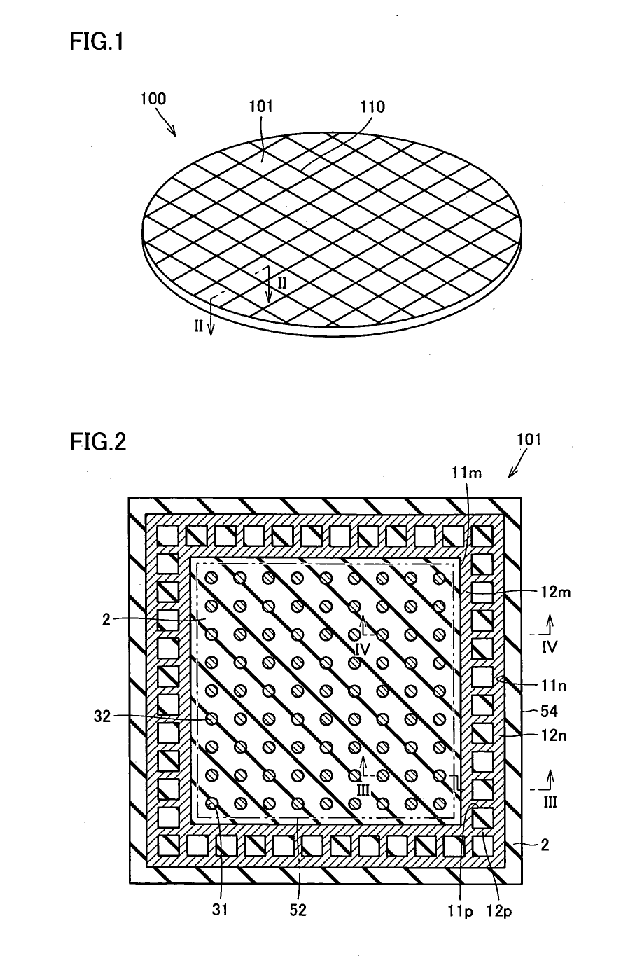

Referring to FIG. 1, a semiconductor wafer 100 is formed of a silicon substrate and a semiconductor element formed on the silicon substrate. On the surface of the semiconductor wafer, dicing lines 110 are formed in a grid. Semiconductor wafer 100 is diced along dicing lines 110 using a dicing saw to obtain therefrom a semiconductor device 101 in the form of a chip.

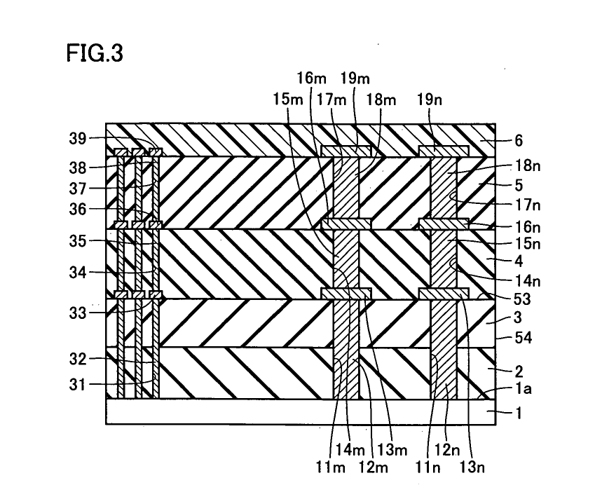

Referring to FIG. 2, a predetermined cross section of semiconductor device 101 obtained from semiconductor wafer 100 in FIG. 1 is shown. Semiconductor device 101 has a rectangular shape in plan view. A peripheral edge 54, which forms the contour of the rectangular shape, is formed of cut surfaces along dicing lines 110. In a memory cell region surrounded by a double-dotted line 52, a memory cell is formed to serve as a semiconductor element.

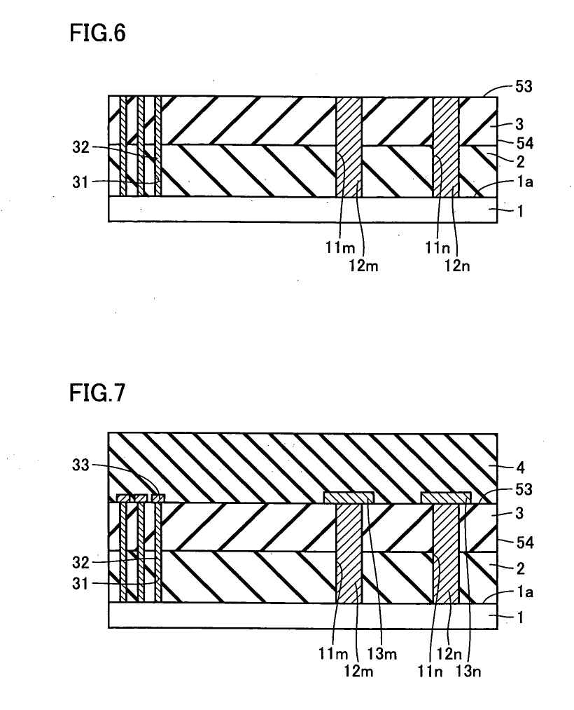

Referring to FIGS. 2 to 4, interlayer insulating films 2 and 3 are successively formed on a main surface la of a silicon substrate 1. Interlayer insulating film 2 is formed on main surface 1a and covers a memory cell which is not shown but placed in the memory cell region. Interlayer insulating films 2 and 3 are of different types from each other, and formed of materials different in hygroscopicity and thermal expansion. Examples of the material forming interlayer insulating films 2 and 3 include tetra ethyl ortho silicate (TEOS), BPTEOS, F-doped silicate glass (FSG), a silicon oxide film and a silicon nitride film doped with phosphorus (P) or boron (B) at a predetermined concentration, and the like.

Interlayer insulating film 3 has a top surface 53 spreading in parallel with main surface 1a. Interlayer insulating films 2 and 3 have a peripheral edge 54 extending from top surface 53 to main surface 1a. Interlayer insulating films 2 and 3 has a hole 31 formed to be placed in the memory cell region surrounded by double-dotted line 52 and to reach main surface 1a from top surface 53. A plurality of holes 31 are arranged in matrix. Each of holes 31 is filled with a metal film 32 made of tungsten (W), aluminum (Al), or the like.

Interlayer insulating films 2 and 3 have grooves 11m and 11n formed outside the memory cell region surrounded by double-dotted line 52. Groove 11n extends along peripheral edge 54 extending in a rectangular shape. Groove 11m extends inside of and in parallel with groove 11n. Grooves 11m and 11n are formed with a predetermined spacing therebetween. Grooves 11m and 11n are formed so as to surround the memory cell region.

Interlayer insulating films 2 and 3 have a groove 11p formed between grooves 11m and 11n. A plurality of grooves 11p are formed to be spaced apart and connect grooves 11m and 11n. Groove 11p extends in a direction orthogonal to the extending direction of grooves 11m and 11n connected by groove 11p. Grooves 11m, 11n and 11p are filled with metal films 12m, 12n and 12p, respectively, which are made of tungsten, aluminum, or the like. Grooves 11m, 11n and 11p are filled with the same material as metal film 32 filling hole 31. Metal films 12m, 12n and 12p, which fill grooves 11m, 11n and 11p, respectively, form a seal ring surrounding the memory cell region. The seal ring is originally provided to serve as a moisture-proof mechanism, and prevents moisture, which is absorbed from peripheral edge 54, from adversely affecting semiconductor device 101.

On top surface 53 of interlayer insulating film 3, a plurality of metal wirings 33 are formed to contact metal film 32. On top surface 53 of interlayer insulating film 3, metal wirings 13m and 13n are formed to contact metal films 12m and 12n, respectively. Metal wirings 13m and 13n are formed along a line along which metal films 12m and 12n shown in FIG. 2 extend. Metal wirings 33, 13m and 13n are made of tungsten, aluminum, or the like.

On interlayer insulating film 3, an interlayer insulating film 4 made of TEOS or the like is formed to cover metal wirings 33, 13m and 13n. Interlayer insulating film 4 has a hole 34 formed to reach metal wiring 33. Interlayer insulating film 4 has grooves 14m and 14n formed to reach metal wirings 13m and 13n, respectively. Grooves 14m and 14n are formed in a position overlapping grooves 11m and 11n, respectively, in plan view. Hole 34, grooves 14m and 14n are filled with metal films 35, 15m and 15n, respectively, which are made of tungsten, aluminum, or the like. Interlayer insulating film 4 further has a seal ring formed of metal wirings 13m and 13n, and metal films 15m and 15n to surround the memory cell region.

On the top surface of interlayer insulating film 4, a plurality of metal wirings 36 are formed to contact metal film 35. On the top surface of interlayer insulating film 4, metal wirings 16m and 16n are formed to contact metal films 15m and 15n, respectively. Metal wirings 16m and 16n are formed along a line along which metal films 12m and 12n shown in FIG. 2 extend. Metal wirings 36, 16m and 16n are made of tungsten, aluminum, or the like.

On interlayer insulating film 4, an interlayer insulating film 5 made of TEOS or the like is formed to cover metal wirings 36, 16m and 16n. Interlayer insulating film 5 has a plurality of holes 37 formed to reach respective metal wirings 36. Interlayer insulating film 5 has grooves 17m and 17n formed to reach metal wirings 16m and 16n, respectively. Grooves 17m and 17n are formed in a position overlapping grooves 11m and 11n, respectively, in plan view. Hole 37, grooves 17m and 17n are filled with metal films 38, 18m and 18n, respectively, which are made of tungsten, aluminum, or the like. Interlayer insulating film 5 further has a seal ring formed of metal wirings 16m and 16n, and metal films 18m and 18n to surround the memory cell region. ,On the top surface of interlayer insulating film 5, a plurality of metal wirings 39 are formed to contact metal film 38. On the top surface of interlayer insulating film 5, metal wirings 19m and 19n are formed to contact metal films 18m and 18n, respectively. Metal wirings 19m and 19n are formed along a line along which metal films 12m and 12n shown in FIG. 2 extend. Metal wirings 39, 19m and 19n are made of tungsten, aluminum, or the like.

On the top surface of interlayer insulating film 5, a protection film 6 made of polyimide, for example, is formed to cover metal wirings 39, 19m and 19n. Though not shown, a plurality of electrodes electrically connected to metal wirings 39, 19m, 19n, and the like are formed in protection film 6.

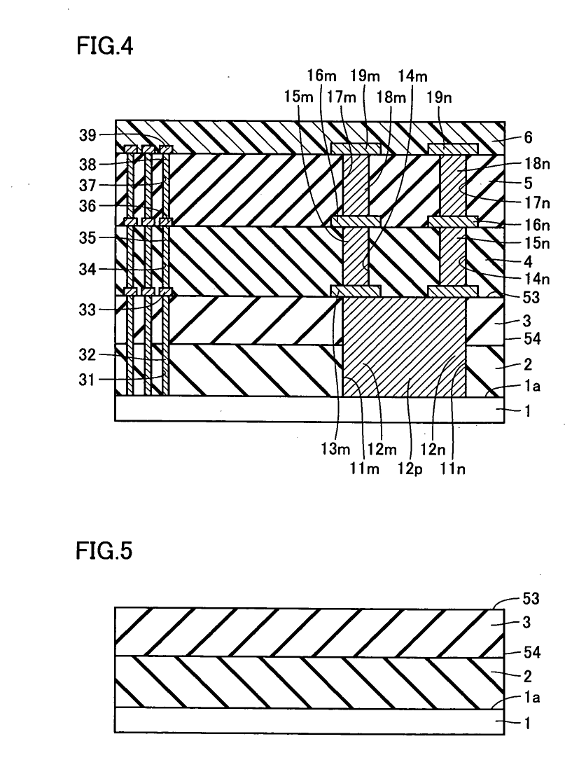

Referring to FIGS. 5 to 8 and FIG. 3, a method of manufacturing a semiconductor device in FIG. 3 is described below.

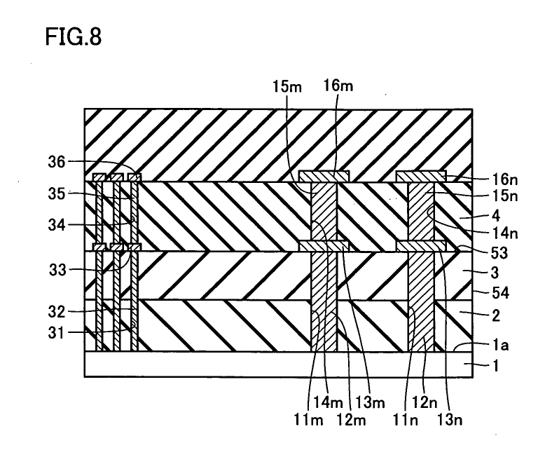

Referring to FIG. 5, interlayer insulating films 2 and 3 made of different materials from each other are successively deposited on main surface 1a of silicon substrate 1. Referring to FIG. 6, interlayer insulating films 2 and 3 are subjected to predetermined processes of photolithography and etching to form hole 31, grooves 11m, 11n and 11p up to main surface 1a. A metal film is deposited to fill hole 31, grooves 11m, 11n and 11p so that metal films 32, 12m, 12n and 12p are formed inside hole 31, grooves 11m, 11n and 11p, respectively.

Generally, when a portion of relatively large area and a portion of relatively small area are simultaneously etched, the portion of relatively large area is etched more easily. Therefore, when a groove of relatively large area and a hole of relatively small area are simultaneously etched, respective etching rates will differ. In the process described above, grooves 11m and 11n are formed along with hole 31 by simultaneous etching. However, since grooves 11m and 11n are formed spaced apart, the present embodiment is superior in etching controllability than the case where a single groove having twice as large width as each of grooves 11m and 11n is formed.

Referring to FIG. 7, on top surface 53 of interlayer insulating film 3, metal wirings 33, 13m and 13n of a prescribed shape are formed. Interlayer insulating film 4 is formed to cover metal wirings 33, 13m and 13n.

Referring to FIG. 8, interlayer insulating film 4 is subjected to predetermined processes of photolithography and etching to form hole 34, grooves 14m and 14n reaching metal wirings 33, 13m and 13n, respectively. Metal films 35, 15m and 15n are formed inside hole 34, grooves 14m and 14n, respectively. Furthermore, on the top surface of interlayer insulating film 4, metal wirings 36, 16m and 16n of a predetermined shape are formed. Interlayer insulating film 5 is formed to cover metal wirings 36, 16m and 16n.

Referring to FIG. 3, interlayer insulating film 5 is subjected to predetermined processes of photolithography and etching to form hole 37, grooves 17m and 17n reaching metal wirings 36, 16m and 16n, respectively. Metal films 38, 18m and 18n are formed inside hole 37, grooves 17m and 17n, respectively. Furthermore, on the top surface of interlayer insulating film 5, metal wirings 39, 19m and 19n of a predetermined shape are formed. Protection film 6 is formed to cover metal wirings 39, 19m and 19n. With the processes described above, the semiconductor device shown in FIG. 3 is completed.

In semiconductor device 101 according to the present embodiment, the metal wiring formed on the top surface of each of the interlayer insulating films forms a part of the seal ring surrounding the memory cell region. Therefore, in the process shown in FIG. 8, for example, when grooves 14m and 14n are formed to reach metal wirings 13m and 13n, respectively, a seal ring contiguous in the upper and lower layers can be formed. This case less likely suffers from the problem of mask displacement in the photolithography process, compared with the case where grooves 14m and 14n are formed to reach metal films 12m and 12n, respectively, which are exposed at top surface 53 of interlayer insulating film 3. Thus, the photolithography process in forming grooves 14m and 14n can easily be performed.

Semiconductor device 101 according to the first embodiment of the present invention includes: silicon substrate 1 serving as a semiconductor substrate having main surface 1a; a memory cell serving as a semiconductor element formed on main surface 1a; and interlayer insulating films 2 and 3 formed on main surface 1a to cover the memory cell. Interlayer insulating films 2 and 3 have top surface 53 and peripheral edge 54 extending from top surface 53 to main surface 1a. In interlayer insulating films 2 and 3, grooves 11m and 11n serving as strip-like first and second groove portions are formed to be placed between the memory cell and peripheral edge 54, to extend in parallel with main surface 1a and to extend in a predetermined direction at a spacing with each other, and a groove 11p serving as a plurality of third groove portions is formed to diverge from grooves 11m and 11n to extend in a direction different from the extending direction of grooves 11m and 11n. Semiconductor device 101 further includes metal films 12m, 12n and 12p filling grooves 11m, 11n and 11p, respectively.

Groove 11p is formed between grooves 11m and 11n. Groove 11p links grooves 11m and 11n. Grooves 11m, 11n and 11p reach main surface 1a from top surface 53. Grooves 11m and 11n are formed along peripheral edge 54 to surround a region where the memory cell is formed (a region surrounded by double-dotted line 52). The interlayer insulating films include interlayer insulating films 2 and 3 serving as first and second portions of different types from each other and successively formed on main surface 1a.

In the present embodiment, groove 11p is provided in two layers, that is, interlayer insulating films 2 and 3. However, groove 11p may be provided extending to interlayer insulating films 4 and 5. In this case, a seal ring structure currently formed in interlayer insulating films 2 and 3 will be formed in four layers, that is, interlayer insulating films 2 to 5.

According to semiconductor device 101 configured as such, grooves 11m, 11n and 11p are filled with the metal film to form the seal ring between the memory cell and peripheral edge 54. Therefore, the seal ring can prevent a crack, which occurs at peripheral edge 54 and propagates therefrom toward the memory cell region surrounded by double-doted line 52, from reaching the memory cell region. Furthermore, the seal ring can prevent the interlayer insulating film from peeling off from main surface 1a of silicon substrate 1.

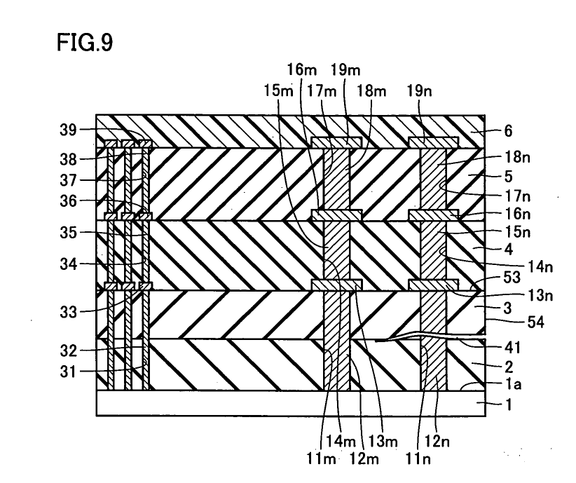

Referring to FIGS. 2 and 9, a crack 41 occurring at peripheral edge 54 initially reaches the seal ring formed of metal film 12n. In this stage, metal film 12n functions as a resistance to weaken the force propagated by crack 41. Furthermore, since a part of the seal ring is formed of metal film 12p diverging from metal films 12m and 12n, the contacting area between interlayer insulating films 2 and 3 and the seal ring is increased. The seal ring is formed to have mechanical engagement with interlayer insulating films 2 and 3. Such an anchoring effect ensures that the seal ring is supported in interlayer insulating films 2 and 3, and thus resistive force of the seal ring against crack 41 can be increased. For the reason described above, crack 41 ceases propagating in the interlayer insulating film between metal films 12m and 12n or in the seal ring formed of metal film 12m.

In the present embodiment, grooves 11m and 11n are connected by groove 11p. Therefore, metal film 12p is provided to link metal films 12m and 12n, which can particularly increase the effect obtained by the anchoring effect described above.

Since groove 11p is placed between grooves 11m and 11n, the seal ring is formed in a region between grooves 11m and 11n. Therefore, the above-mentioned effect resulting from providing metal film 12p can be obtained without increasing an area intended to form the seal ring, which also allows smaller semiconductor device to be formed.

Furthermore, in semiconductor device 101, the seal ring made of metal films 12m, 12n and 12p is formed contiguously from top surface 53 of interlayer insulating film 3 to main surface 1a. Furthermore, the seal ring is formed to surround the entire memory cell region in semiconductor device 101. For such reason, any crack generated in peripheral edge 54 can be surely prevented from reaching inside the memory cell region.

When interlayer insulating films 2 and 3 are formed of different materials from each other as in the case of the present embodiment, a crack will be readily generated at the border between interlayer insulating films 2 and 3 because of difference in hygroscopicity and thermal expansion. The present invention can thus be used much effectively in semiconductor device 101 with such configuration. Furthermore, in a semiconductor device where a single-layer interlayer insulating film is formed on a semiconductor substrate, a crack can occur from the peripheral edge which has absorbed moisture. The present invention can also be used much effectively in such a semiconductor device.

### Second Embodiment

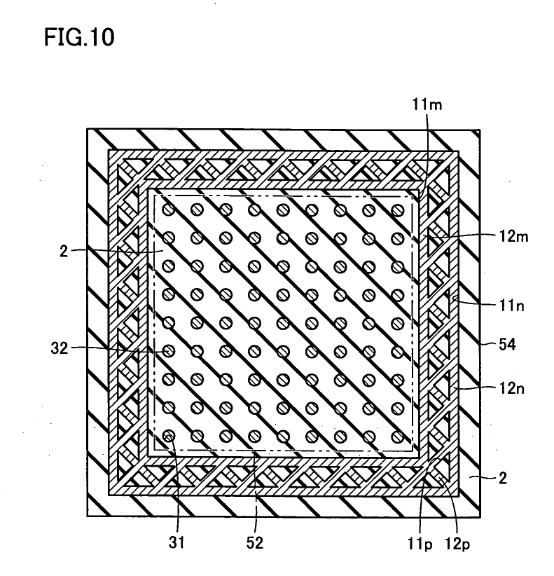

FIG. 10 shows a configuration corresponding to a cross section shown in FIG. 2 in the first embodiment. A semiconductor device in a second embodiment has basically the same structure as that of the semiconductor device in the first embodiment, except for the shape of the seal ring formed in the interlayer insulating film. Hereinafter, for the similar structure, description thereof will not be repeated.

Referring to FIG. 10, in interlayer insulating films 2 and 3, grooves 11m and 11n are formed to be placed outside the memory cell region surrounded by double-dotted line 52, and groove 11p is formed to extend in zigzag between grooves 11m and 11n. Groove 11p connects grooves 11m and 11n at each predetermined spacing. Groove 11p extends in a direction diagonal to the extending direction of grooves 11m and 11n connected by groove 11p.

According to the semiconductor device configured as such, the effect similar to that of the first embodiment can be obtained. Furthermore, since three seal rings are formed in some regions from peripheral edge 54 to the memory cell region, a larger effect of preventing crack propagation can be obtained in these regions.

### Third Embodiment

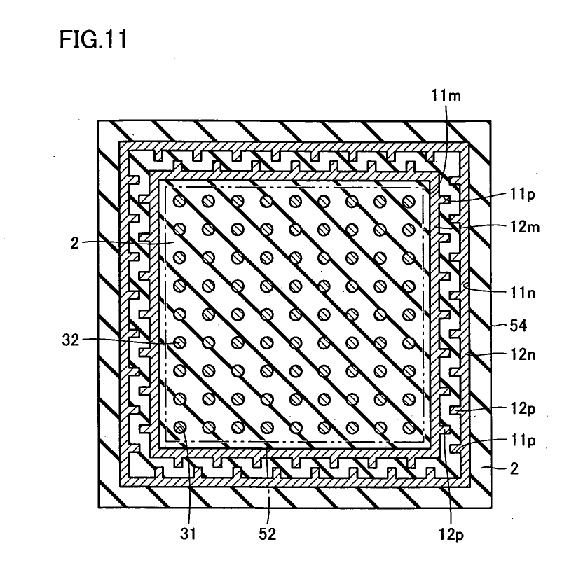

FIG. 11 shows a configuration corresponding to a cross section shown in FIG. 2 in the first embodiment. A semiconductor device in a third embodiment has basically the same structure as that of the semiconductor device in the first embodiment, except for the shape of the seal ring formed in the interlayer insulating film. Hereinafter, for the similar structure, description thereof will not be repeated.

Referring to FIG. 11, in interlayer insulating films 2 and 3, grooves 11m and 11n are formed to be placed outside the memory cell region surrounded by double-dotted line 52, and a plurality of grooves 11p are formed to be placed between grooves 11m and 11n and to extend in a direction orthogonal to the extending direction of grooves 11m and 11n. Grooves 11p protrude from both grooves 11m and 11n, and grooves 11p protruding from one of the grooves extend toward the other groove. Grooves 11p protrude from both grooves 11m and 11n alternately at a predetermined spacing with each other.

According to the semiconductor device configured as such, the effect similar to that of the first embodiment can be obtained.

For the first to third embodiments, only the case where groove 11p is formed between grooves 11m and 11n is described. However, the present invention is not limited thereto. Groove 11p may be shaped to extend outside grooves 11m and 11n.

### Fourth Embodiment

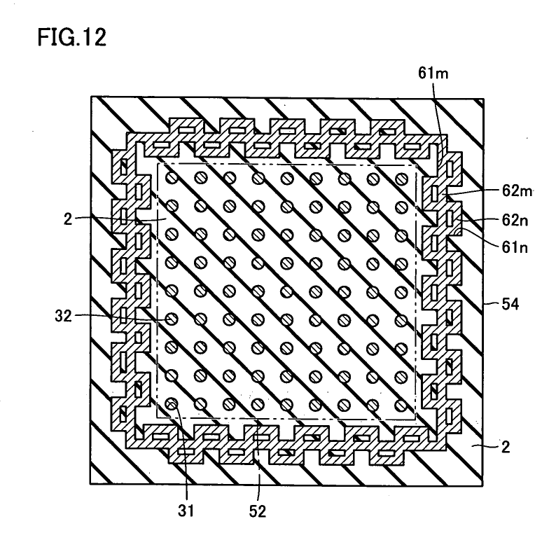

FIG. 12 shows a configuration corresponding to a cross section shown in FIG. 2 in the first embodiment. A semiconductor device in a fourth embodiment has basically the same structure as that of the semiconductor device in the first embodiment, except for the shape of the seal ring formed in the interlayer insulating film. Hereinafter, for the similar structure, description thereof will not be repeated.

Referring to FIG. 12, in interlayer insulating films 2 and 3, groove 61m is formed to be placed outside the memory cell region surrounded by double-dotted line 52. Groove 61m extends along peripheral edge 54 to surround the memory cell region. In interlayer insulating films 2 and 3, groove 61n is formed to cross groove 61m at predetermined spacing. Groove 61n generally extends in the extending direction of groove 61m while changing its extending direction for every 90 degrees. Groove 61n crosses groove 61m in a direction orthogonal to the extending direction of groove 61m. Grooves 61m and 61n are filled with metal films 62m and 62n, respectively, which are made of tungsten, aluminum, or the like. Metal films 62m and 62n filling grooves 61m and 61n, respectively, form the seal ring surrounding the memory cell region.

A semiconductor device in the fourth embodiment of the present invention includes: silicon substrate 1 serving as a semiconductor substrate having main surface 1a; a memory cell serving as a semiconductor element formed on main surface 1a; and interlayer insulating films 2 and 3 formed on main surface 1a to cover the memory cell. Interlayer insulating films 2 and 3 have top surface 53 and peripheral edge 54 extending from top surface 53 to main surface 1a. In interlayer insulating films 2 and 3, grooves 61m and 61n serving as strip-like first and second groove portions are formed to be placed between the memory cell and peripheral edge 54, to extend in parallel with main surface 1a, and to extend to cross each other at predetermined spacing. The semiconductor device further includes metal films 62m and 62n serving as a metal filling grooves 61m and 61n, respectively.

Grooves 61m and 61n reach main surface 1a from top surface 53. Grooves 61m and 61n are formed along peripheral edge 54 to surround a region where a memory cell is formed. The interlayer insulating films include interlayer insulating films 2 and 3 serving as first and second portions of different types from each other and successively formed on main surface 1a.

According to the semiconductor device configured as such, grooves 61m and 61n are filled with the metal film to form the seal ring between the memory cell and peripheral edge 54. Since groove 61m crosses groove 61n, metal films 62m and 62n filling grooves 61m and 61n, respectively, are formed to have mechanical engagement with interlayer insulating films 2 and 3. Therefore, the seal ring can obtain the anchoring effect described above. Thus, in the semiconductor device according to this embodiment, an effect similar to that of the first embodiment can also be obtained.

Furthermore, the seal ring formed of metal films 62m and 62n is formed contiguously from top surface 53 of interlayer insulating film 3 to main surface 1a. Furthermore, the seal ring is formed to surround the memory cell region of the semiconductor device. Therefore, for an effect resulting from such configuration, an effect similar to that of the first embodiment can also be obtained.

Furthermore, for the reason described in the first embodiment, the present invention can be used much effectively in a semiconductor device where interlayer insulating films 2 and 3 are made of different materials from each other. Furthermore, the present invention can be used much effectively in a semiconductor device where a single-layer interlayer insulating film is formed on a semiconductor substrate.

### Fifth Embodiment

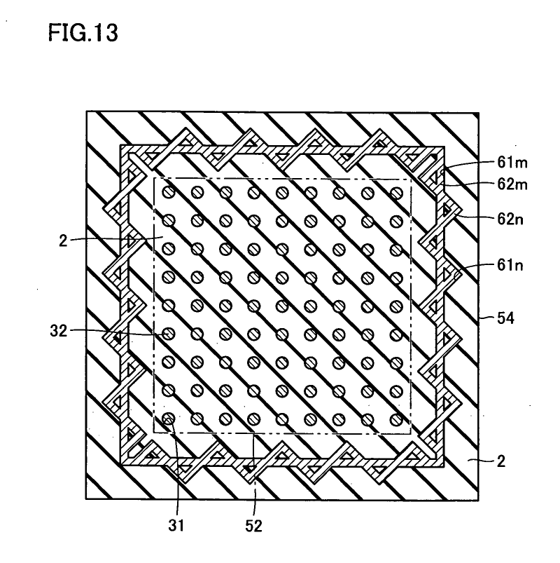

FIG. 13 shows a configuration corresponding to a cross section shown in FIG. 2 in the first embodiment. A semiconductor device in a fifth embodiment has basically the same structure as that of the semiconductor device in the fourth embodiment, except for the shape of the seal ring formed in the interlayer insulating film. Hereinafter, for the similar structure, description thereof will not be repeated.

Referring to FIG. 13, in interlayer insulating films 2 and 3, groove 61m is formed to be placed outside the memory cell region surrounded by double-dotted line 52 and to extend along peripheral edge 54, and groove 61n is formed to cross groove 61m at predetermined spacing. Groove 61n is formed to extend in zigzag, and crosses groove 61m in a direction diagonal to the extending direction of groove 61m.

According to the semiconductor device configured as such, an effect similar to that of the fourth embodiment can be obtained.

### Sixth Embodiment

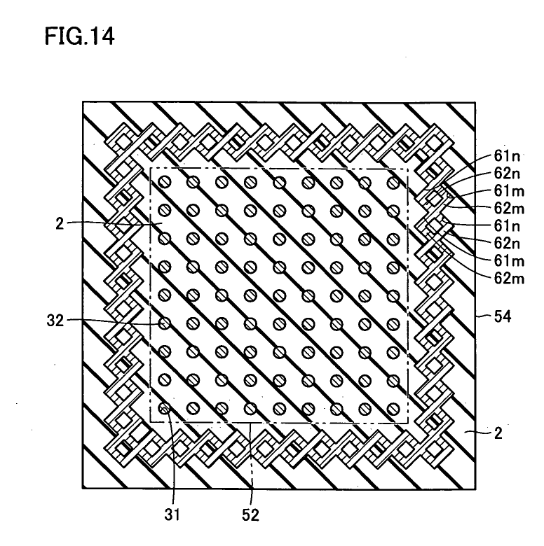

FIG. 14 shows a configuration corresponding to a cross section shown in FIG. 2 in the first embodiment. A semiconductor device in a sixth embodiment has basically the same structure as that of the semiconductor device in the fourth embodiment, except for the shape of the seal ring formed in the interlayer insulating film. Hereinafter, for the similar structure, description thereof will not be repeated.

Referring to FIG. 14, in interlayer insulating films 2 and 3, grooves 61m and 61n are formed to be placed outside the memory cell region surrounded by double-dotted line 52 and to extend in zigzag. Grooves 61m and 61n has the same shape, but are formed to be displaced from each other. Groove 61m thus crosses groove 61n at predetermined spacing.

According to the semiconductor device configured as such, an effect similar to that of the fourth embodiment can be obtained.

### Seventh Embodiment

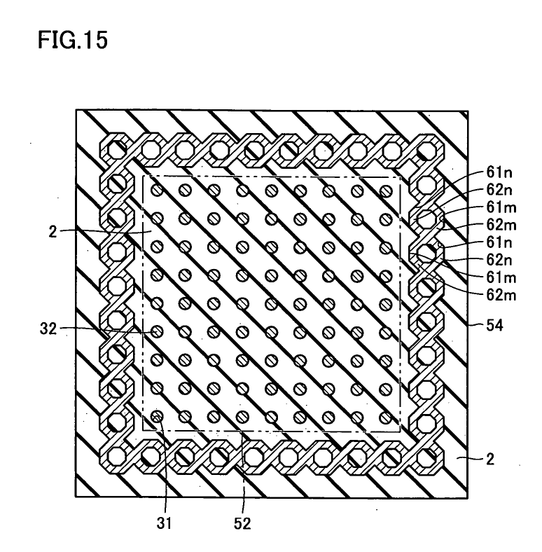

FIG. 15 shows a configuration corresponding to a cross section shown in FIG. 2 in the first embodiment. A semiconductor device in a seventh embodiment has basically the same structure as that of the semiconductor device in the fourth embodiment, except for the shape of the seal ring formed in the interlayer insulating film. Hereinafter, for the similar structure, description thereof will not be repeated.

Referring to FIG. 15, in interlayer insulating films 2 and 3, grooves 61m and 61n are formed to cross each other at predetermined spacing. Grooves 61m and 61n cross each other to form a honeycomb structure.

According to the semiconductor device configured as such, an effect similar to that of the fourth embodiment can be obtained. Furthermore, since grooves 61m and 61n form a honeycomb structure, strength and stiffness of the seal ring can be increased.

Although the present invention has been described in detail, it is clearly understood that the same is by way of illustration only and is not to be taken by way of limitation, the spirit and scope of the present invention being limited only by the terms of the appended claims.

1. A semiconductor device comprising:
a semiconductor substrate having a main surface;
a semiconductor element formed on said main surface;
an interlayer insulating film having a top surface and a peripheral edge extending from said top surface to said main surface, and formed on said main surface to cover said semiconductor element, wherein in said interlayer insulating film, strip-like first and second groove portions are formed to be placed between said semiconductor element and said peripheral edge, to extend in parallel with said main surface and to extend in a predetermined direction at a spacing with each other, and a plurality of third groove portions are formed to diverge from said first and second groove portions and to extend in a direction different from an extending direction of said first and second groove portions; and
a metal filling said first, second and third groove portions.

2. The semiconductor device according to claim 1, wherein said third groove portion is formed between said first groove portion and said second groove portion.

3. The semiconductor device according to claim 1, wherein said third groove portion links said first groove portion and said second groove portion.

4. The semiconductor device according to claim 1, wherein said first, second and third groove portions reach said main surface from said top surface.

5. The semiconductor device according to claim 1, wherein said first and second groove portions are formed along said peripheral edge to surround a region where said semiconductor element is formed.

6. The semiconductor device according to claim 1, wherein said interlayer insulating film includes first and second portions of different types from each other and successively formed on said main surface.

7. A semiconductor device comprising:
a semiconductor substrate having a main surface;
a semiconductor element formed on said main surface;
an interlayer insulating film having a top surface and a peripheral edge extending from said top surface to said main surface, and formed on said main surface to cover said semiconductor element, wherein in said interlayer insulating film, strip-like first and second groove portions are formed to be placed between said semiconductor element and said peripheral edge, to extend in parallel with said main surface and to extend to cross each other at predetermined spacing; and
a metal filling said first and second groove portions.

8. The semiconductor device according to claim 7, wherein said first and second groove portions reach said main surface from said top surface.

9. The semiconductor device according to claim 7, wherein said first and second groove portions are formed along said peripheral edge to surround a region where said semiconductor element is formed.

10. The semiconductor device according to claim 7, wherein said interlayer insulating film includes first and second portions of different types from each other and successively formed on said main surface.
